(19) United States
(12) Patent Application Publication
(10) Pub. No.: US 2010/0270265 A1
(43) Pub. Date: Oct. 28, 2010

(54) METHOD FOR ADSORPTION OF NANO-STRUCTURE AND ADSORPTION MATTER USING SOLID THIN FILM MASK

(76) Inventors: Seung-Hun Hong, Seoul (KR); Tae-Kyeong Kim, Gyeonggi-do (KR)

Correspondence Address: IP & T Law Firm PLC, 7700 Little River Turnpike, Suite 207, Annandale, VA, 22003, US

(21) Appl. No.: 12/747,396

(22) PCT Filed: Nov. 18, 2008
(86) PCT No.: PCT/KR08/06787

§ 371 Date: Jun. 10, 2010

(30) Foreign Application Priority Data
Dec. 10, 2007 (KR) 10-2007-0127849

(51) Int. Cl. B05D 1/32; B05D 3/10; C23C 14/34

(52) U.S. Cl. 216/89; 427/282; 204/192.12; 977/888; 977/890

(57) ABSTRACT

A method of adsorbing a nano-structure and an adsorption material using a solid thin film mask, including; depositing the mask over the entire surface of a tip of a probe microscope, grinding the end of the tip having the mask against a solid, thus removing the mask from the end of the tip, depositing a linker molecule layer over the entire surface of the tip the end of which has no mask, immersing the tip having the deposited linker molecule layer in a nano-structure solution, thus adsorbing the nano-structure on the linker molecule, and removing the mask from the tip. The mask is used to prevent deformation of the tip, and the nano-structure and the adsorption material can be deposited only on the end of the tip, regardless of the properties of the nano-structure and the adsorption material and regardless of the surface material of the tip and the properties thereof.

### TECHNICAL FIELD

The present invention relates to techniques for adsorbing a nano-structure and an adsorption material on a tip of a scanning probe microscope, and more particularly, to a method of adsorbing a nano-structure and an adsorption material using a solid thin film mask, in which the solid thin film mask is used to prevent the deformation of the tip of the scanning probe microscope, and the nano-structure and the adsorption material can be deposited only on the tip of the scanning probe microscope, regardless of the properties of the nano-structure and the adsorption material which are adsorbed and also regardless of the surface material of the tip of the probe microscope and the properties thereof.

### BACKGROUND ART

Recently, it is possible that a measurement with nanometer resolution in the material world is realized due to the rapid development of a scanning probe microscope. The major part to determine the resolution of the scanning probe microscope is the end portion of the probe, currently the most widely used probe is made of materials such as Si₃N₄, Si or the like and the radius of the end portion of the probe reaches below 10 nm. However, it is very difficult to control the shape or the property of the probe end portion which is the major part according to the user's demand by current technology.

On the other hand, due to the rapid development of recent nano-technology, nano-structures with the uniform shape made of various materials have been developed. For example, there are various nano-particles or various nano-wires made of Au, Ag, CdSe or the like and optical properties, electrical properties, shapes, sizes thereof can be very exactly controlled. And, such development of nano-technology allows further precise scanning probe microscope to be developed. If various nano-structures or adsorption materials the shapes or sizes of which have been precisely controlled are able to be adsorbed only on the end portion of the probe microscope, the properties of conventional probe microscopes may be drastically improved. Further, it is possible to develop a novel type of probe microscope and as well to develop the nano-optical measurement types such as nano-FRET (nano-Fluorescent Resonance Energy Transfer), nano-SERS (nano-Surface-Enhanced Raman Scattering) or the like. Furthermore, the tip on which the nano-structure having a uniform shape is adsorbed enables the nano-scale force to be more reliably measured, compared to conventional measurements.

Thus, techniques for adsorbing the nano-structure and the adsorption material on a tip of the probe microscope are being developed. Currently, methods of coating the entire surface of a probe with a nano-structure and of adsorbing a nano-structure using an adsorption prevention molecular film are widely employed.

The method of coating the entire surface of tip of the probe microscope with the nano-structure includes, as shown in FIG. 1, coating the entire surface of the tip T of the probe microscope with a CdSe fluorescent nano-structure N. When using the tip thus obtained, nano-FRET imaging can be realized. However, this method is problematic because the nano-structure N is attached to the entire surface of the tip T, drastically lowering the resolution.

With the goal of solving the above problem, methods of utilizing selective adsorption force of a nano-structure and an adsorption material using the adsorption prevention molecular film have been devised. As shown in FIG. 2, the typical process thereof includes sequentially depositing an Au film 10 and an adsorption prevention molecular film 20 having a very low ability to adsorb a nano-structure N on the surface of a tip T of a probe microscope, removing the Au film 10 and the adsorption prevention molecular film 20 which are deposited on the end of the tip T, and depositing a linker molecule layer 30 having a high ability to adsorb the nano-structure N on the end of the tip T having neither Au film nor adsorption prevention molecular film. Then, the nano-structure N is adsorbed, so that the nano-structure N is selectively adsorbed on the linker molecule layer 30 of the end of the tip T.

According to the method using the adsorption prevention molecular film, however, many organics including an adsorption prevention thin film used for preventing the adsorption of the nano-structure are permanently present on the probe of the probe microscope, and thus the properties of the probe itself may change. Also, the above method is unable to adsorb materials which are adsorbable through sputtering or evaporation, and thus, many limitations are imposed on the usable types of nano-structure or adsorption material. As well, depending on the surface material of the tip and the properties thereof, problems are caused by the necessary use of the adsorption prevention molecular film and the restrictions its use imposes.

### DISCLOSURE

### Technical Problem

Accordingly, the present invention is intended to adsorb a nano-structure or an adsorption material only on the end of a tip of a probe microscope. For this purpose, a solid thin film mask is deposited over the entire surface of the tip of the probe microscope, and the end of tip having the solid thin film mask deposited over the entire surface thereof grinds against the surface of a solid, thus removing only the end portion of the solid thin film mask which was deposited over the entire surface of the tip. Then, the nano-structure or the adsorption material (in the case of the nano-structure, a linker molecule layer is adsorbed and then the nano-structure is adsorbed) is adsorbed on the entire surface of the tip, so that the nano-structure or the adsorption material can be adsorbed both on the surface of the solid thin film mask and on the surface having no solid thin film mask. Then, the solid thin film mask is removed from the surface of the tip, so that the nano-structure or the adsorption material adsorbed on the surface of the solid thin film mask can be removed together. Thereby, only the nano-structure or the adsorption material which is adsorbed on the surface having no solid thin film mask remains.

### Technical Solution

An aspect of the present invention provides a method of adsorbing a nano-structure and an adsorption material using a solid thin film mask, including a) depositing a solid thin film mask on a tip of a probe microscope; b) grinding the end of the tip having the solid thin film mask deposited thereon against the surface of a solid, thus removing only the solid thin film mask which was deposited on the end of the tip from the entire deposited solid thin film mask; c) depositing a linker molecule layer on the tip only the end of which has no solid thin film mask; d) immersing the tip having the linker molecule layer deposited thereon in a nano-structure solution thus adsorbing the nano-structure on the linker molecule layer; and e) removing the solid thin film mask deposited on the tip.

In addition, another aspect of the present invention provides a method of adsorbing a nano-structure and an adsorption material using a solid thin film mask, including a) depositing a solid thin film mask on a tip of a probe microscope; b) grinding the end of the tip having the solid thin film mask deposited thereon against the surface of a solid, thus removing only the solid thin film mask deposited on the end of the tip from the entire deposited solid thin film mask; c′) depositing an adsorption material on the tip only the end of which has no solid thin film mask; and d′) removing the solid thin film mask deposited on the tip.

In the present invention, b) removing only the solid thin film mask deposited on the end of the tip may be performed by bringing the end of the tip into contact with the surface of the solid and then scanning an end region of the tip having a size of 10 μm 10 μm for a period of time ranging from 1 sec to 1 day using a force of 10˜500 nN.

In the present invention, b) removing only the solid thin film mask deposited on the end of the tip may be performed through CMP (Chemical Mechanical Polishing).

In the present invention, c) depositing the linker molecule layer on the tip having no solid thin film mask may be performed by immersing the tip in a linker molecule solution for a period of time ranging from 1 sec to 10 days and then washing off the tip with anhydrous hexane.

In the present invention, c) depositing the linker molecule layer on the tip having no solid thin film mask may be performed by heating the linker molecule solution in a closed container thus generating steam, which is then brought into contact with the tip for a period of time ranging from 1 sec to 10 days.

In the present invention, d) immersing the tip having the linker molecule layer deposited thereon in the nano-structure solution thus adsorbing the nano-structure on the linker molecule layer may be performed by immersing the tip in the nano-structure solution for 1 hour or longer.

In the present invention, c′) depositing an adsorption material over the entire surface of tip only the end of which has no solid thin film mask may be performed by depositing the nano-structure through sputtering or evaporation.

The solid thin film mask may include aluminum (Al).

The linker molecule solution may be an aminopropyltriethoxysilane solution.

### DESCRIPTION OF DRAWINGS

FIG. 1 is of a schematic view and a SEM (Scanning Electron Microscope) image showing a state where a nano-structure is adsorbed on the entire surface of a tip of a probe microscope according to a conventional technique;

FIG. 2 is a schematic view showing a process of adsorbing a nano-structure using an adsorption prevention molecular film according to another conventional technique;

FIG. 3 is a schematic view showing a process of adsorbing a nano-structure using a solid thin film mask according to a first embodiment of the present invention;

FIG. 4 is of SEM images showing the state of the nano-structure adsorbed on the end of the tip before and after removal of the solid thin film mask according to the process of FIG. 3;

FIG. 5 is a schematic view showing a process of adsorbing an adsorption material using a solid thin film mask according to a second embodiment of the present invention;

FIG. 6 is an SEM image showing the state of the adsorption material adsorbed on the end of the tip after removal of the solid thin film mask according to the process of FIG. 5;

FIG. 7 is a schematic view showing a process of adsorbing an adsorption material using a solid thin film mask according to a third embodiment of the present invention; and

FIG. 8 is an SEM image showing the state of the adsorption material adsorbed on the end of the tip after removal of the solid thin film mask according to the process of FIG. 7.

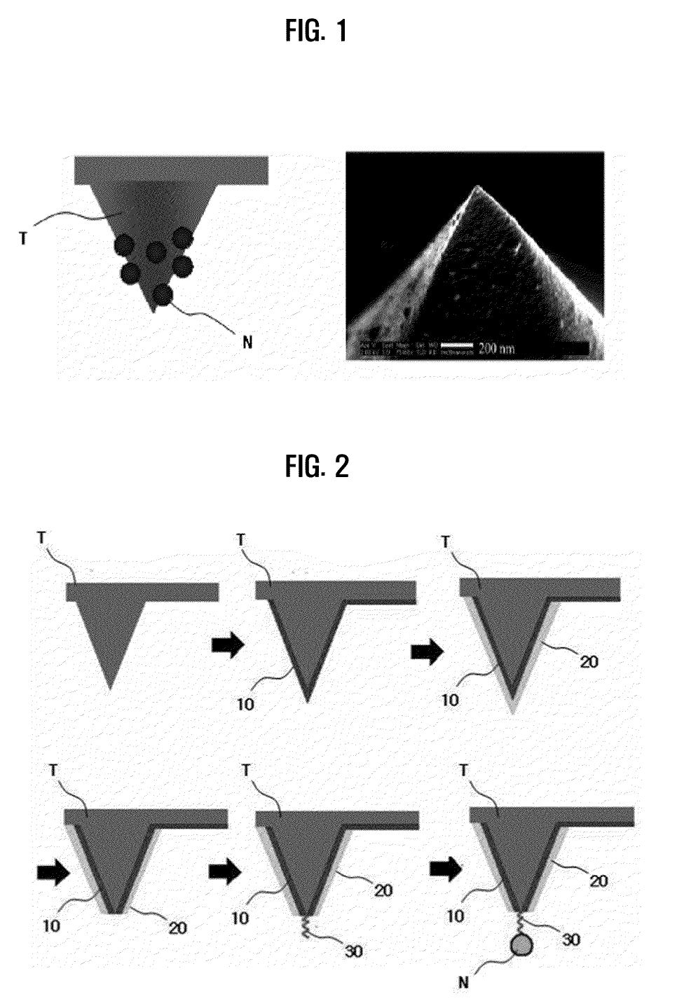

### BEST MODE

Hereinafter, a detailed description will be given of constructions and effects of the preferred embodiments of the present invention with reference to the appended drawings.

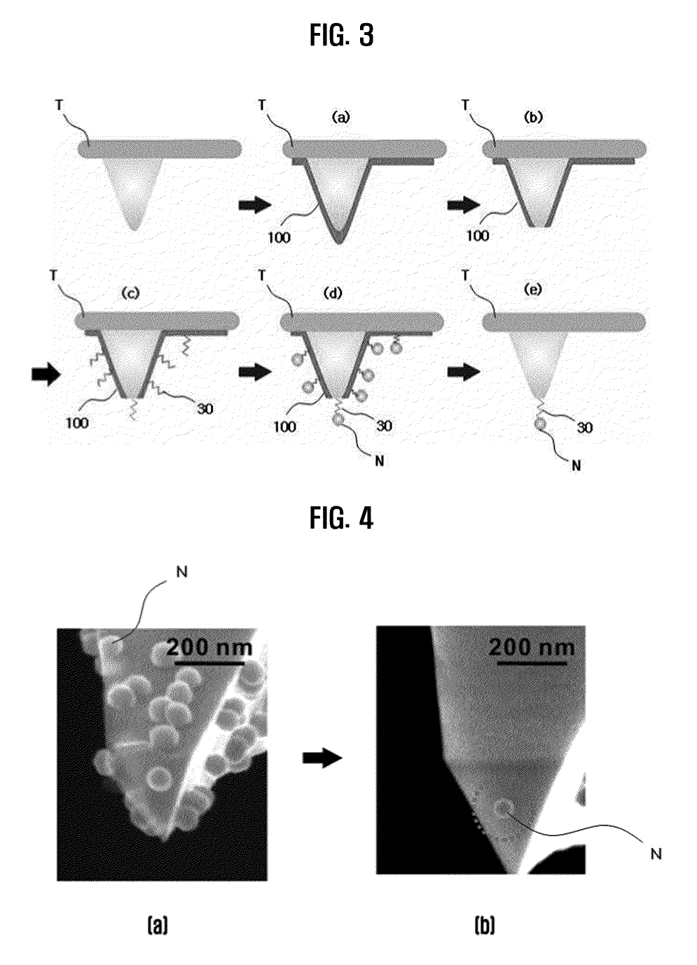

FIG. 3 is a schematic view showing a process of adsorbing a nano-structure using a solid thin film mask according to a first embodiment of the present invention, and FIG. 4 is of SEM images showing the state of the nano-structure adsorbed on the end of the tip before and after removal of the solid thin film mask according to the process of FIG. 3.

According to the first embodiment of the present invention, the method of adsorbing a nano-structure N on the end of a tip T is described below. As shown in FIG. 3, the method includes a) depositing a solid thin film mask 100 over the entire surface of the tip T, b) grinding the end of the tip T having the solid thin film mask 100 deposited thereon against the surface of a solid thus removing only the solid thin film mask 100 deposited on the end of the tip T from the entire deposited solid thin film mask 100, c) depositing a linker molecule layer 30 over the entire surface of the tip T only the end of which has no solid thin film mask 100, d) immersing the tip T having the linker molecule layer 30 deposited thereon in a nano-structure solution thus adsorbing the nano-structure N on the linker molecule layer 30 ((a) of FIG. 4), and e) removing the solid thin film mask 100 deposited on the tip T. Thereby, as seen in (a) and (b) of FIG. 4, after the removal of the solid thin film mask 100, the nano-structure N is adsorbed only on the end of the tip T.

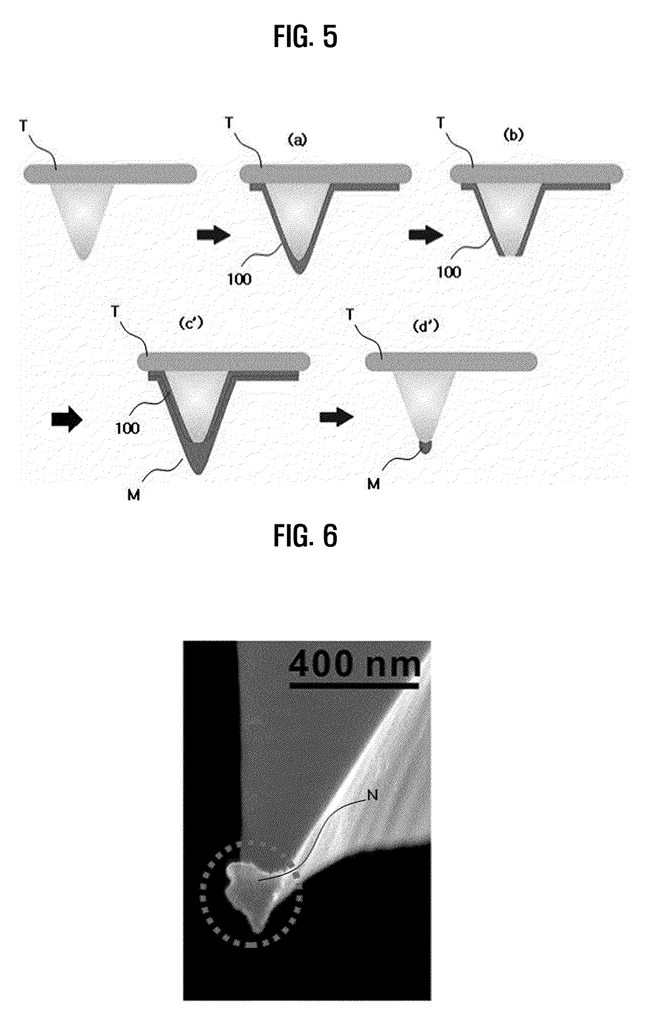

FIG. 5 is a schematic view showing a process of adsorbing an adsorption material using a solid thin film mask according to a second embodiment of the present invention, and FIG. 6 is an SEM image showing the state of the adsorption material adsorbed on the end of the tip after removal of the solid thin film mask according to the process of FIG. 5.

According to the second embodiment of the present invention, the method of adsorbing an adsorption material M on the end of a tip of a probe microscope is described below. As shown in FIG. 5, the method includes a) depositing a solid thin film mask 100 over the entire surface of a tip T of a probe microscope, b) grinding the end of the tip T having the solid thin film mask 100 deposited thereon against the surface of a solid thus removing only the solid thin film mask 100 deposited on the end of the tip T from the entire deposited solid thin film mask 100, c′) depositing an adsorption material M over the entire surface of the tip T only the end of which has no solid thin film mask 100, and d′) removing the solid thin film mask 100 deposited on the tip T. Thereby, as seen in FIG. 6, after the removal of the solid thin film mask 100, the adsorption material N is adsorbed only on the end of the tip T.

In the method of adsorbing the nano-structure and the adsorption material using the solid thin film mask according to the first and second embodiments of the present invention (FIGS. 3 to 6), an alternative to the removal of the solid thin film mask is described below.

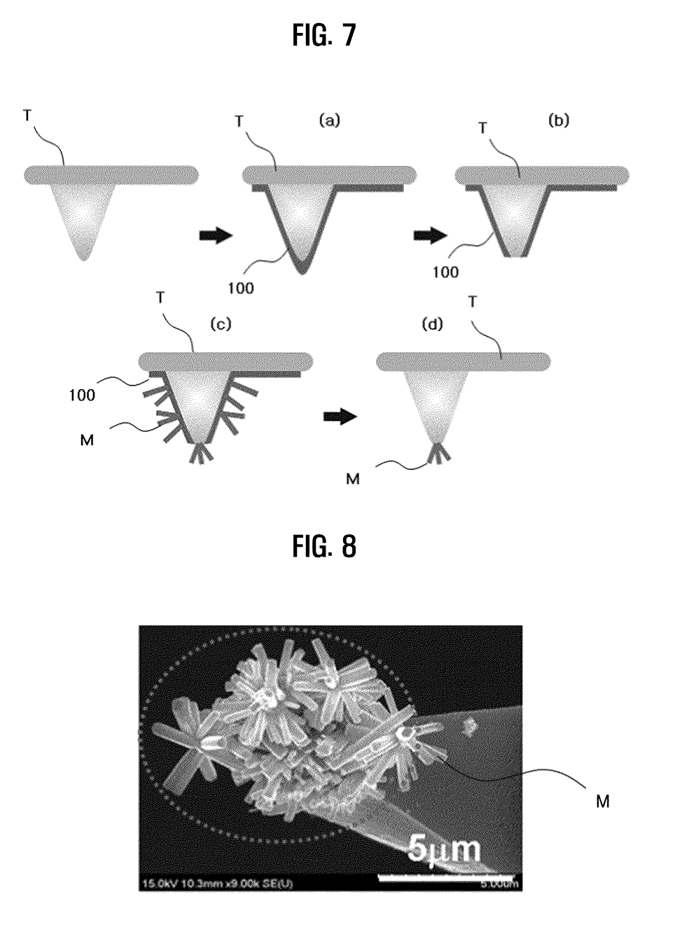

As shown in FIGS. 7 and 8, a basic solution may be used to remove the solid thin film mask. In the case where the basic solution is used, the solid thin film mask can be completely removed, thus maintaining the surface properties of the probe microscope.

### MODE FOR INVENTION

The constructions and effects of the preferred embodiments of the present invention are specifically described below.

### First Embodiment

### 1^{st} Embodiment

### Adsorption of Nano-Structure N to End of Tip T of Probe Microscope

According to the first embodiment, a gold (Au) nano-structure is used as the nano-structure and aluminum (Al) is used as the solid thin film mask. An aminopropyltriethoxysilane solution is used as a linker molecule solution.

On the surface of a tip of a probe microscope, an aluminum solid thin film mask 10-100 nm thick is deposited, and the tip is mounted in a probe microscope. Then, the tip is brought into contact with the surface of silicon dioxide (SiO₂), and a predetermined end region thereof having a size of 10 μm×10 μm is scanned for a predetermined period of time using a force of about 10˜500 nN, thus removing the solid thin film mask from the end of the tip. Through these procedures, the section of the end of the tip having no mask has an average diameter ranging from 30 nm to 1000 nm, and the conditions for polishing or CMP may be controlled in order to achieve the above diameter.

As the solid thin film mask, Al, Ti, SiO₂, tin oxide, Co, Pd, Ag, Cr, Pb or the like may be used, in addition to Al.

On the other hand, in the case where a plurality of tips is worked at the same time, CMP for flattening a semiconductor wafer may be used, or scanning wafer-scale tips in contact with the surface of silicon dioxide (SiO₂) may be employed.

Subsequently, the tip the end of which has no solid thin film mask is immersed in a solution of aminopropyltriethoxysilane in anhydrous hexane for about 30 min. Thereby, aminopropyltriethoxysilane is deposited on the end of the tip and is also slightly deposited on the surface of the aluminum (Al) solid thin film mask. Alternatively, the aminopropyltriethoxysilane solution may be heated in a closed container, thus generating steam, which is then brought into contact with the tip for a predetermined period of time, thus depositing aminopropyltriethoxysilane on the surface of the Al solid thin film mask.

The tip thus obtained is immersed in a solution of gold (Au) nano-structure having a diameter of 50 nm for 1 hour or longer, thereby adsorbing the nano-structure both on the end of the probe having aminopropyltriethoxysilane deposited thereon and on the surface of the solid thin film mask. Thereafter, the tip is immersed in an aluminum etchant (phosphoric acid:nitric acid:acetic acid=16:1:1), thus peeling off the solid thin film mask to thus remove the nano-structure attached to the surface of the mask together, finally obtaining the gold (Au) nanoparticles adsorbed only on the end of the tip.

The aluminum etchant used for removing the solid thin film mask is exemplary, and, depending on the type of solid thin film mask, various solutions including a basic solution or an etching solution may be applied.

### Second Embodiment

### 2^{nd} Embodiment

### Adsorption of adsorption material M to End of Tip T of Probe Microscope

According to the second embodiment, the metal Au is used as the adsorption material and aluminum (Al) is used as the solid thin film mask.

On the surface of a tip of a probe microscope, an aluminum solid thin film mask 10-100 nm thick is deposited, after which the tip is mounted in a probe microscope. Then, the tip is brought into contact with the surface of silicon dioxide (SiO₂), and a predetermined end region thereof having a size of 10 μm×10 μm is scanned for a predetermined period of time using a force of about 10˜500 nN, thus removing the solid thin film mask from the end of the tip.

As the solid thin film mask, Al, Ti, SiO₂, tin oxide, Co, Pd, Ag, Cr, Pb or the like may be used, in addition to Al. Examples of the adsorption material include, in addition to Au, conductive nanoparticles including Ni, Ag, Ti, Cr, Pt, ZnO, tin oxide, Pb, CeO₂ and SiO₂, fluorescent nanoparticles including CdSe, CdS, ZnS, GaN, GaAs, PbSe, InAs, CdTe and PbS, magnetic nanoparticles including Fe₃O₄, CoPt, Ni/NiO, FeAl, FePt, Co and CoO, CNTs (Carbon Nanotubes), SAMs (Self Assembled Monolayers), DNAs (DeoxyriboNucleic Acids), RNAs (RiboNucleic Acids), proteins, antigens, antibodies, cells and so on.

On the other hand, in the case where a plurality of tips is worked at the same time, CMP for flattening a semiconductor wafer may be used, or scanning wafer-scale tips in contact with the surface of silicon dioxide (SiO₂) may be adopted.

Subsequently, over the entire surface of the tip subjected to the above procedures, the metal (Au) is deposited to a thickness of 10˜1000 nm through sputtering or evaporation, thereby adsorbing the metal (Au) both on the end of the probe and on the surface of the solid thin film mask. Thereafter, the tip is immersed in an aluminum etchant (phosphoric acid:nitric acid:acetic acid=16:1:1), thus peeling off the solid thin film mask to hence remove the metal attached to the surface of the mask together, ultimately obtaining the metal adsorbed only on the end of the tip.

The aluminum etchant used for removing the solid thin film mask is exemplary, and depending on the type of solid thin film mask, various solutions (e.g. a basic solution or an etching solution) may be applied.

In the above embodiments, the solid thin film mask can be completely removed from the surface of the tip together with various adsorption materials attached to the mask, thus preventing the change in the properties of the tip. Further, all materials adsorbable through sputtering or evaporation can be adsorbed on the end of the tip, regardless of the properties of the nano-structure and the adsorption material. Furthermore, the nano-structure and the adsorption material can be adsorbed regardless of the surface material of the tip and the properties thereof.

As is apparent from the above embodiments, the tip having the nano-structure or the adsorption material adsorbed thereon can have a resolution several times higher than that of a conventional tip, and can also be applied in such fields as nano-FRET, nano-SERS imaging, magnetic force probe microscopy, etc.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

### INDUSTRIAL APPLICABILITY

According to the present invention, a nano-structure and an adsorption material are adsorbed on a tip of a probe microscope using a solid thin film mask and then the solid thin film mask is completely removed from the surface of the tip together with various adsorption materials attached to the mask, thus preventing a change in the properties of the tip. Further, it is possible to adsorb, on the end of the tip, all materials adsorbable through PVD (Physical Vapor Deposition) including thermal evaporation, DC sputtering, RF sputtering, ion beam sputtering, pulsed laser deposition or molecular beam epitaxy, or CVD (Chemical Vapor Deposition) including thermal CVD, low pressure CVD, plasma enhanced CVD or metal-organic CVD, regardless of the properties of the nano-structure and the adsorption material. As well, the nano-structure and the adsorption material can be adsorbed regardless of the surface material of the tip and the properties thereof.

Moreover, the solid thin film mask can be completely removed from the surface of the tip together with various adsorption materials attached to the mask, thus preventing the change in the properties of the tip. Without limitation of the nano-structure and the adsorption material, all materials adsorbable through sputtering or evaporation can be adsorbed on the end of the tip. As well, the nano-structure and the adsorption material can be adsorbed regardless of the surface material of the tip and the properties thereof.

1. A method of adsorbing a nano-structure and an adsorption material using a solid thin film mask, comprising:
a) depositing a solid thin film mask over an entire surface of a tip of a probe microscope;
b) grinding an end of the tip having the solid thin film mask deposited thereon against a surface of a solid, thus removing the solid thin film mask deposited on the end of the tip from the entire deposited solid thin film mask;
c) depositing a linker molecule layer over the entire surface of the tip the end of which has no solid thin film mask;
d) immersing the tip having the linker molecule layer deposited thereon in a nano-structure solution, thus adsorbing the nano-structure on the linker molecule layer; and
e) removing the solid thin film mask deposited on the tip.

2. A method of adsorbing a nano-structure and an adsorption material using a solid thin film mask, comprising:
a) depositing a solid thin film mask over an entire surface of a tip of a probe microscope;
b) grinding an end of the tip having the solid thin film mask deposited thereon against a surface of a solid, thus removing the solid thin film mask deposited on the end of the tip from the entire deposited solid thin film mask;
c′) depositing an adsorption material over the entire surface of the tip the end of which has no solid thin film mask; and
d′) removing the solid thin film mask deposited on the tip.

3. The method according to claim 1, wherein the b) is performed by bringing the end of the tip into contact with the surface of the solid and then scanning an end region of the tip having a size of 10 μm×10 μm for a period of time ranging from 1 sec to 1 day using a force of 10˜500 nN.

4. The method according to claim 1, wherein the b) is performed through chemical mechanical polishing.

5. The method according to claim 1, wherein the c) is performed by immersing the tip in a linker molecule solution for a period of time ranging from 1 sec to 10 days and then washing off the tip with anhydrous hexane.

6. The method according to claim 1, wherein the c) is performed by heating a linker molecule solution in a closed container thus generating steam, which is then brought into contact with the tip for a period of time ranging from 1 sec to 10 days.

7. The method according to claim 1, wherein the d) is performed by immersing the tip in the nano-structure solution for 1 hour or longer.

8. The method according to claim 2, wherein the c′) is performed by depositing the adsorption material through sputtering or evaporation.

9. The method according to claim 1, wherein the solid thin film mask comprises any one selected from among Al, Ti, SiO₂, tin oxide, Co, Pd, Ag, Cr and Pb.

10. The method according to claim 5, wherein the linker molecule solution is an aminopropyltriethoxysilane solution.

11. The method according to claim 1, wherein the solid thin film mask deposited on the tip is removed using a basic solution.

12. The method according to claim 6, wherein the linker molecule solution is an aminopropyltriethoxysilane solution.

13. The method according to claim 2, wherein the b) is performed by bringing the end of the tip into contact with the surface of the solid and then scanning an end region of the tip having a size of 10 μm×10 μm for a period of time ranging from 1 sec to 1 day using a force of 10˜500 nN.

14. The method according to claim 2, wherein the b) is performed through chemical mechanical polishing.

15. The method according to claim 2, wherein the solid thin film mask deposited on the tip is removed using a basic solution.
